(19) United States
(12) Patent Application Publication
(10) Pub. No.: US 2011/0235280 A1
(43) Pub. Date: Sep. 29, 2011

(54) HEAT DISSIPATION APPARATUS AND ELECTRONIC ASSEMBLY WITH SAME

(75) Inventor: YI-SHIH HSIEH, Tu-Cheng (TW)

(73) Assignee: FOXCONN TECHNOLOGY CO., LTD., Tu-Cheng (TW)

(21) Appl. No.: 12/765,780

(22) Filed: Apr. 22, 2010

(30) Foreign Application Priority Data
Mar. 24, 2010 (CN) 201010131443.6

(51) Int. Cl. H05K 7/20; F28F 7/00

(52) U.S. Cl. 361/720; 165/185

(57) ABSTRACT

A heat dissipation apparatus includes a heat sink and fasteners. The heat sink defines a plurality of through holes therein. An inner thread is formed on an inner surface of each through hole. Each fastener includes a bolt and a spring around the bolt. The bolt includes a main post, a cap formed on a top of the main post, and a engaging portion formed on a bottom of the main post. A retaining thread is formed on an outer surface of the main post near the engaging portion. The retaining thread matches the inner thread of the through hole. The retaining thread of the main post is configured to pass through the through hole by threading the retaining thread though the inner thread of the through hole. After the retaining thread has passed through the through hole, the retaining thread abuts a bottom surface of the heat sink.

### BACKGROUND

1. Technical Field

The present disclosure generally relates to heat dissipation, and particularly to a heat dissipation apparatus for electronic components.

2. Description of Related Art

With developments in technology, increased performance of electronic components such as CPUs (central processing units) has been achieved. However, such electronic components generate increased levels of heat, which must be dissipated promptly. Conventionally, a heat sink is attached to an electronic component to remove the generated heat. The heat sink is secured on a circuit board on which the electronic component is mounted.

The heat sink generally defines a plurality of through holes therein. The circuit board defines a plurality of receiving holes therein, corresponding to the through holes of the heat sink. A plurality of fasteners such as screws pass through the through holes of the heat sink, respectively, and are received in the receiving holes of the circuit board to secure the heat sink to the electronic component.

Before the heat sink is secured to the circuit board, the fasteners are generally preassembled to the heat sink. To maintain the fasteners on the heat sink, a gasket is generally clipped on a bottom portion of each fastener after the fastener extends through the heat sink. However, the gasket increases the cost of the heat sink. In addition, a tool is often needed to clip the gasket on the fastener. Furthermore, after the heat sink is secured to the circuit board, the gasket has no further use, and may even drop down onto circuitry of the circuit board. If the gasket is made of electrically conductive material, it may cause a short circuit.

Therefore, what is needed is a heat dissipation apparatus which can overcome the described limitations.

### BRIEF DESCRIPTION OF THE DRAWINGS

FIG. 1 is an exploded cross-section of a heat dissipation apparatus in accordance with an embodiment of the present disclosure, together with an electronic component mounted on a circuit board.

FIG. 2 is an assembled view of FIG. 1.

FIG. 3 is an exploded cross-section of a heat dissipation apparatus in accordance with an alternative embodiment of the present disclosure, together with an electronic component mounted on a circuit board.

FIG. 4 is an assembled view of FIG. 3.

### DETAILED DESCRIPTION

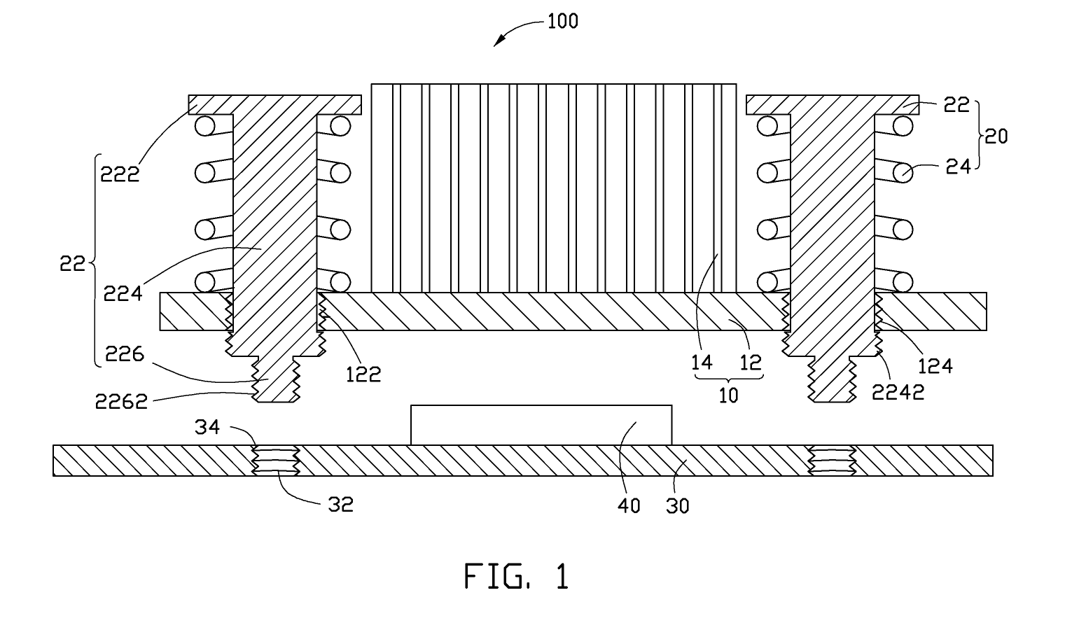

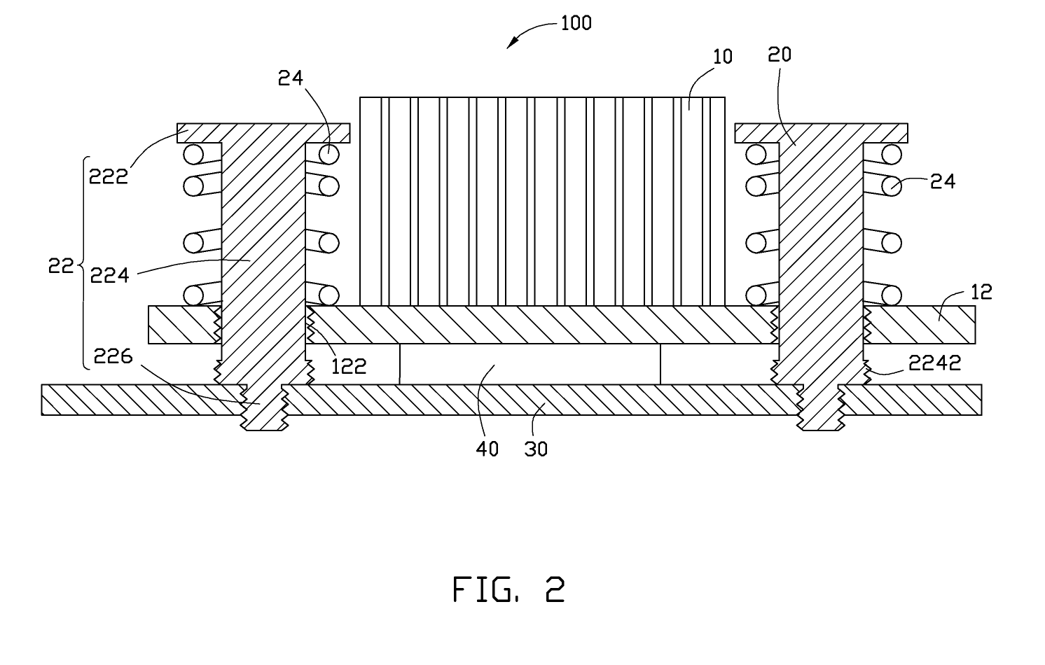

Referring to FIGS. 1 and 2, a heat dissipation apparatus 100 according to an embodiment of the present disclosure is shown. The heat dissipation apparatus 100 is configured for dissipating heat from an electronic component 40, such as a CPU (central processing unit) mounted on a circuit board 30 of a computer. The heat dissipation apparatus 100 includes a heat sink 10, and a plurality of fasteners 20 fixing the heat sink 10 on the circuit board 30 on which the electronic component 40 is mounted. A plurality of receiving holes 32 is defined in the circuit board 30 around the electronic component 40. An inner thread 34 is formed on an inner surface of each receiving hole 32.

The heat sink 10 includes a base plate 12, and a plurality of fins 14 extending upwardly from a top surface of the base plate 12. A bottom surface of the base plate 12 is configured to be attached to the electronic component 40 to absorb heat therefrom. A plurality of through holes 122 is defined in the base plate 12 beside the fins 14. The through holes 122 are coaxial with the receiving holes 32 of the circuit board 30. An inner thread 124 is formed on an inner surface of each through hole 122. The fasteners 20 are preassembled in the through holes 122 of the base plate 12 of the heat sink 10.

Each fastener 20 includes a bolt 22, and a spring 24 coiled around the bolt 22. The bolt 22 includes a main post 224, a cap 222 formed at a top end of the main post 224, and a engaging portion 226 formed at a bottom end of the main post 224. The cap 222 has a diameter greater than that of the main post 224 and the spring 24. The engaging portion 226 has a diameter less than that of the main post 224. The main post 224 has a diameter less than that of the corresponding through hole 122 of the heat sink 10. The engaging portion 226 has a diameter substantially the same as that of the corresponding receiving hole 32 of the circuit board 30. An outer thread 2262 is formed on an outer surface of the engaging portion 226 for engaging the inner thread 34 of the receiving hole 32 of the circuit board 30. The spring 24 is coiled around the main post 224 of the bolt 22.

A retaining thread 2242 is formed on an outer surface of a bottom portion of the main post 224 that is adjacent to the engaging portion 226. The retaining thread 2242 matches the inner thread 124 of the through hole 122 of the heat sink 10. The bottom portion of the main post 224 can pass through the through hole 122 of the heat sink 10 by threading the retaining thread 2242 of the main post 226 with the inner thread 124 of the through hole 122. After the retaining thread 2242 has passed through the through hole 122, the main post 226 is held in the through hole 122 by the retaining thread 2242. Thus, the fasteners 20 can safely remain with the heat sink 10 during transport. The spring 24 is sandwiched between the cap 222 of the bolt 22 and the top surface of the base plate 12 to keep the bolt 22 upright.

In assembling the heat sink 10 to the circuit board 30, the receiving portion 226 of each fastener 20 is threadedly engaged with the inner thread 34 in the corresponding receiving hole 32 of the circuit board 30, thereby securing the heat sink 10 to the electronic component 40, as shown in FIG. 2. The spring 24 is compressed downwardly by the cap 222 to generate a downward force impelling the heat sink 10 downwardly towards the electronic component 40.

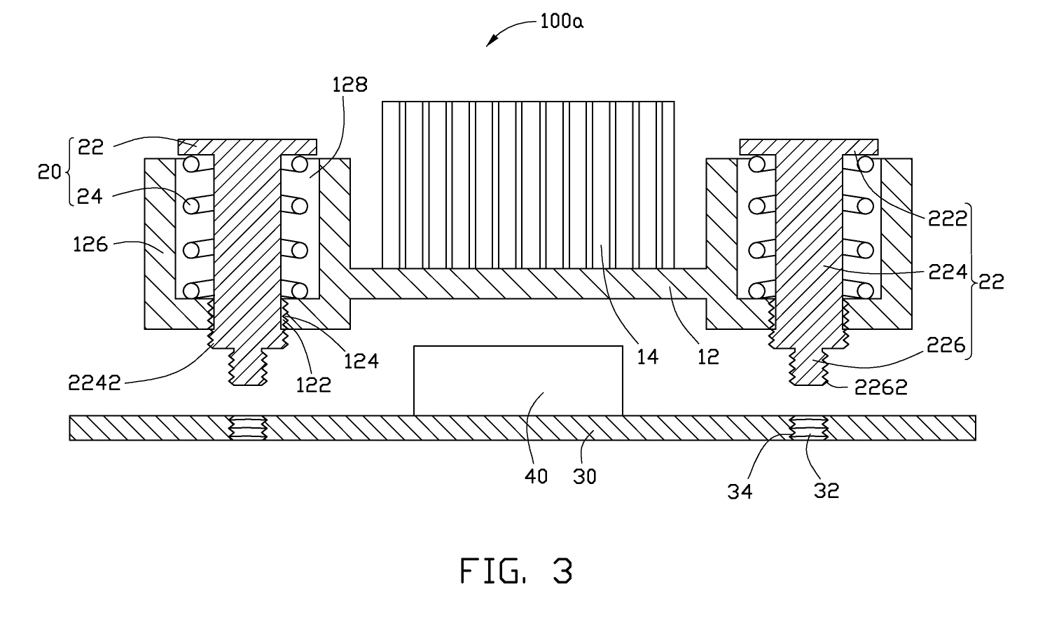

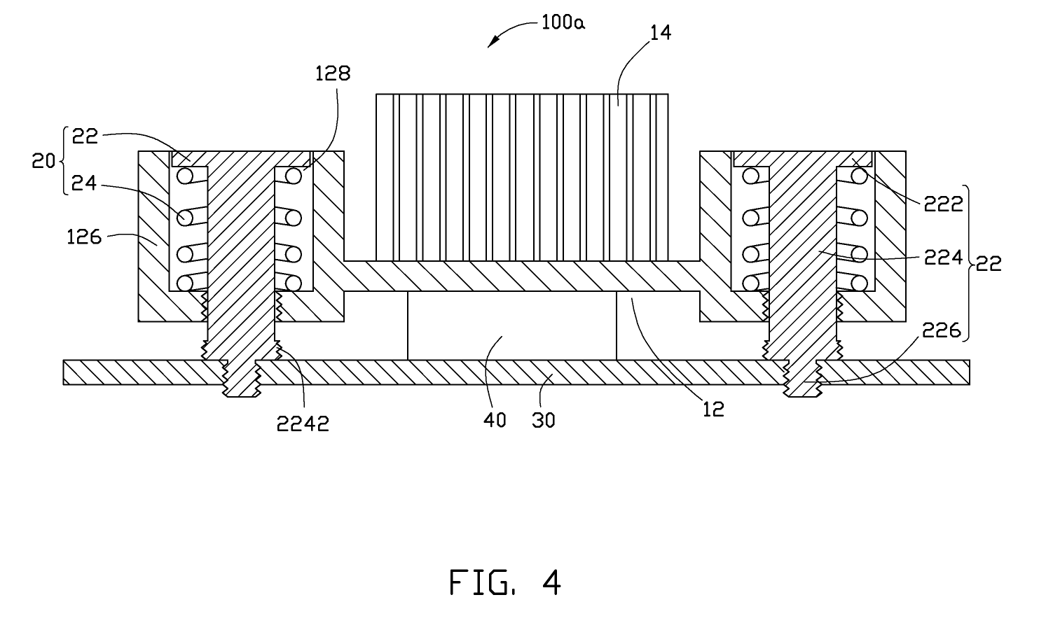

An alternative heat dissipation apparatus 100a is shown in FIGS. 3-4. The heat dissipation apparatus 100a differs from the previous heat dissipation apparatus 100 as follows. A sleeve 126 is formed on the base plate 12 around each through hole 122. The base plate 12 is offset to a lower level where the sleeves 126 are located. A receiving space 128 is defined in each sleeve 126 for receiving the corresponding fastener 20 therein, such that the fastener 20 can be located in the through hole 122 of the heat sink 10 more securely.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipation apparatus, comprising:
a heat sink defining a plurality of through holes therein, an inner thread formed on an inner surface of each through hole; and
a plurality of fasteners assembled in the through holes of the heat sink, respectively, each fastener comprising a bolt and a spring coiled around the bolt, the bolt comprising a main post, a cap formed on a top of the main post, and a engaging portion formed on a bottom of the main post;
wherein a retaining thread is formed on an outer surface of the main post above the engaging portion, the retaining thread matches the inner thread of the corresponding through hole of the heat sink, and the retaining thread of the main post is configured to pass through the through hole of the heat sink by threading the retaining thread of the main post through the inner thread of the through hole; and
wherein after the retaining thread has passed through the through hole, the retaining thread abuts a bottom surface of the heat sink, and the spring is sandwiched between the cap and the heat sink.

2. The heat dissipation apparatus of claim 1, wherein the heat sink comprises a base plate and a plurality of fins extending from the base plate, and the through holes are defined in the base plate beside the fins.

3. The heat dissipation apparatus of claim 2, wherein the spring is coiled around the main post of the bolt and sandwiched between the cap and the base plate of the heat sink.

4. The heat dissipation apparatus of claim 2, wherein a sleeve is formed on the base plate around each through hole, a receiving space is defined in the sleeve, and a corresponding fastener is received in the sleeve.

5. The heat dissipation apparatus of claim 1, wherein the engaging portion of the bolt has a diameter less than that of the main post, and an outer thread is formed on an outer surface of the engaging portion.

6. The heat dissipation apparatus of claim 1, wherein the retaining thread is formed on the outer surface of the main post adjacent to the engaging portion.

7. An electronic assembly, comprising:
a circuit board defining a plurality of receiving holes therein;
an electronic component mounted on the circuit board;
a heat sink mounted on the electronic component, the heat sink defining a plurality of through holes therein, an inner thread formed on an inner surface of each through hole; and
a plurality of fasteners attached in the through holes of the heat sink, respectively, each fastener comprising a bolt and a spring coiled around the bolt, the bolt comprising a main post, a cap formed on a top of the main post, and a engaging portion formed on a bottom of the main post, the engaging portion of each fastener received in a corresponding receiving hole of the circuit board, the spring compressed between the cap and the heat sink to exert a downward force impelling the heat sink towards the electronic component;
wherein a retaining thread is formed on an outer surface of the main post above the engaging portion, the retaining thread matches the inner thread of the corresponding through hole of the heat sink, and the retaining thread of the main post is configured to pass through the through hole of the mounting arm by threading the retaining thread of the main post through the inner thread of the through hole.

8. The electronic assembly of claim 7, wherein the heat sink comprises a base plate and a plurality of fins extending from the base plate, and the through holes are defined in the base plate beside the fins.

9. The electronic assembly of claim 8, wherein the spring is coiled around the main post of the bolt and sandwiched between the cap and the base plate of the heat sink.

10. The electronic assembly of claim 8, wherein a sleeve is formed on the base plate around each through hole, a receiving space is defined in the sleeve, and a corresponding fastener is received in the sleeve.

11. The electronic assembly of claim 7, wherein the engaging portion of the bolt has a diameter less than that of the main post, and an outer thread is formed on an outer surface of the engaging portion.

12. The electronic assembly of claim 7, wherein retaining thread is formed on the outer surface of the main post adjacent to the engaging portion.
